(19) United States
(12) Patent Application Publication
(10) Pub. No.: US 2010/0214135 A1
(43) Pub. Date: Aug. 26, 2010

(54) DYNAMIC REAR-PROJECTED USER INTERFACE

(75) Inventors: Steven N. Bathiche, Kirkland, WA (US); Adrian R.L. Travis, Kirkland, WA (US); Neil Emerton, Redmond, WA (US); Timothy A. Large, Bellevue, WA (US); David Stephen Zucker, Seattle, WA (US)

Correspondence Address: MICROSOFT CORPORATION, ONE MICROSOFT WAY, REDMOND, WA, 98052, US

(73) Assignee: Microsoft Corporation, Redmond, WA (US)

(21) Appl. No.: 12/393,901

(22) Filed: Feb. 26, 2009

(51) Int. Cl. H03M 11/26

(52) U.S. Cl. 341/23; 353/28; 341/31

(57) ABSTRACT

A dynamic projected user interface includes a light source for generating a light beam and a spatial light modulator for receiving and dynamically modulating the light beam to create a plurality of display images that are respectively projected onto a plurality of keys in a keyboard. An optical arrangement is disposed in an optical path between the light source and the spatial light modulator for conveying the light beam from the light source to the spatial light modulator.

### BACKGROUND

The functional usefulness of a computing system is determined in large part by the modes in which the computing system outputs information to a user and enables the user to make inputs to the computing system. A user interface generally becomes more useful and more powerful when it is specially tailored for a particular task, application, program, or other context of the operating system. Perhaps the most widely spread computing system input device is the keyboard, which provides alphabetic, numeric, and other orthographic keys, along with a set of function keys, that are generally of broad utility among a variety of computing system contexts. However, the functions assigned to the function keys are typically dependent on the computing context and are assigned often very different functions by different contexts. Additionally, the orthographic keys are often assigned non-orthographic functions, or need to be used to make orthographic inputs that do not necessarily correspond with the particular orthographic characters that are represented on any keys of a standard keyboard, often only by simultaneously pressing combinations of keys, such as by holding down either or any combination of a control key, an “alt” key, a shift key, and so forth. Factors such as these limit the functionality and usefulness of a keyboard as a user input device for a computing system.

Some keyboards have been introduced to address these issues by putting small liquid crystal display (LCD) screens on the tops of the individual keys. However, this presents many new problems of its own. It typically involves providing each of the keys with its own Single Twisted Neumatic (STN) LCD screen, LCD driver, LCD controller, and electronics board to integrate these three components. One of these electronics boards must be placed at the top of each of the mechanically actuated keys and connect to a system data bus via a flexible cable to accommodate the electrical connection during key travel. All the keys must be individually addressed by a master processor/controller, which must provide the electrical signals controlling the LCD images for each of the keys to the tops of the keys, where the image is formed. Such an arrangement tends to be very complicated, fragile, and expensive. In addition, the flexible data cable attached to each of the keys is subject to mechanical wear-and-tear with each keystroke.

The discussion above is merely provided for general background information and is not intended to be used as an aid in determining the scope of the claimed subject matter.

### SUMMARY

A dynamic projected user interface is disclosed in a variety of different implementations. According to one illustrative embodiment, a dynamic projected user interface includes a light source for generating a light beam and a spatial light modulator for receiving and dynamically modulating the light beam to create a plurality of display images that are respectively projected onto a plurality of keys in a keyboard. An optical arrangement is disposed in an optical path between the light source and the spatial light modulator for conveying the light beam from the light source to the spatial light modulator.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

FIG. 1 illustrates a dynamic rear-projected user interface device, according to an illustrative embodiment.

FIG. 2A illustrates a dynamic rear-projected user interface device, according to another illustrative embodiment.

FIG. 2B illustrates a dynamic rear-projected user interface device, according to another illustrative embodiment.

FIG. 3 illustrates a dynamic rear-projected user interface device, according to another illustrative embodiment.

FIG. 4 illustrates a key assembly for a display-type key which may be employed in a dynamic rear-projected user interface device.

FIG. 5 illustrates a dynamic rear-projected user interface device, according to another illustrative embodiment.

### DETAILED DESCRIPTION

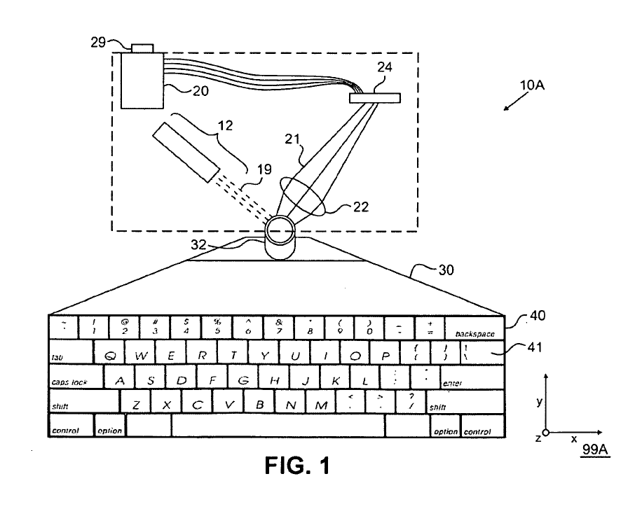

FIG. 1 depicts a dynamic rear-projected user interface device 10A, according to an illustrative embodiment. Dynamic rear-projected user interface 10 may be illustrative of embodiments that include devices, computing systems, computing environments, and contexts that enable associated method embodiments and associated executable instructions configured to be executable by computing systems, for example. The following discussion provides further details of an illustrative sampling of various embodiments. The particular illustrative embodiments discussed below are intended as illustrative and indicative of the variety and broader meaning associated with the disclosure and the claims defined below.

As depicted in FIG. 1, dynamic rear-projected user interface device 10A is depicted in a simplified block diagram that includes keyboard 40 (which includes individual keys 41), light source 12, imaging controller 20, and imaging sensor 24. Light source 12 may illustratively includes a laser, an LED array, a cathode ray, or other type of light source, which emits a light beam 19 in any frequency range, though typically at least in part in the visible spectrum. FIG. 1 is not meant to represent the actual optics of dynamic rear-projected user interface device 10A or the actual path of beam 19, which are readily within design choices that may be made within the understanding of those skilled in the art. Rather, FIG. 1 demonstrates a simplified block diagram to make clear the concepts involved.

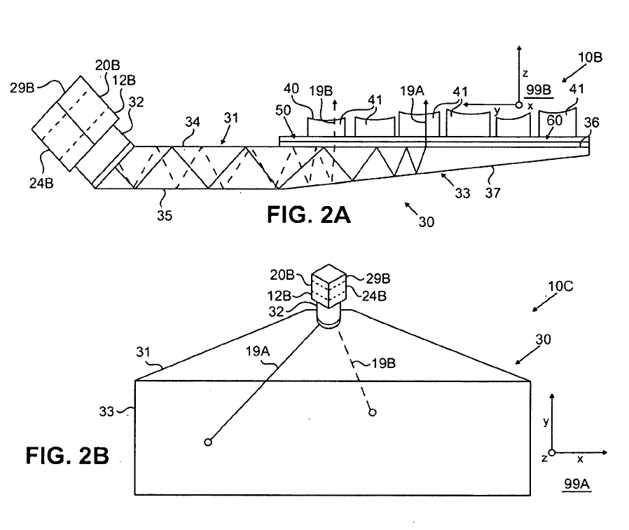

Light beam 19 follows a beam path into waveguide nexus 32 of waveguide 30. The subsequent path of light beam 19 will be described with reference to FIGS. 2A and 2B, which are described below. Coordinate set 99A is depicted in the corner of FIG. 1, for purposes of correlating the depiction of dynamic rear-projected user interface device 10A in FIG. 1 with additional depictions in later figures. Coordinate set 99A shows an X direction going from left to right of the keyboard 40, a Y direction going from bottom to top of keyboard 40, and a Z direction going from down to up, “out of the page” and perpendicular to the plane of keyboard 40.

Keyboard 40 does not have any static characters or symbols pre-printed onto any of the surfaces of the keys 41; rather, the lower or inner surfaces of the keys 41 are configured to be translucent and to serve as the display surfaces for images that are uniquely provided to each of the keys 41 by the light beam 19 emitted by the light source 12 after the light source is modulated by a spatial light modulator, which will be described in greater detail in connection with FIGS. 2A and 2B.

With continued reference to FIG. 1, lens 22 is disposed adjacent to imaging sensor 24, and is configured to receive optical signals returned from the surfaces of the keys 41 and to focus them onto imaging sensor 24. Imaging sensor 24 may illustratively be composed mainly of a complementary metal-oxide-semiconductor (CMOS) array, for example. It may also be a different type of imager such as a charge-coupled device (CCD), a single pixel photodetector with a scanned beam system, or any other type of imaging sensor.

Imaging controller 20 is configured to receive and operate according to instructions from a computing device (not shown in FIG. 1). Imaging controller 20 communicates with an associated computing device through communication interface 29, which may include a wired interface such as according to one of the Universal Serial Bus (USB) protocols, for example, or may take the form of any of a number of wireless protocols. Imaging controller 20 is also configured to return inputs detected through imaging sensor 24 to the associated computing system. The associated computing system may be running any of a variety of different applications or other operating contexts, which may determine the output and input modes in effect at a particular time for dynamic rear-projected user interface device 10A.

Imaging sensor 24 is configured, such as by being disposed in connection with the waveguide 30, to receive optical signals coming in the reverse direction in which the light beam is being provided by light source 12, from the surfaces of the keys 41. Imaging sensor 24 may therefore optically detect when one of the keys 41 is pressed. For example, imaging sensor 24 may be enabled to detect when the edges of one of keys 41 approaches or contacts the surface of waveguide 30, in one illustrative embodiment. Because the surfaces of the keys 41 are semi-transparent, in this embodiment, imaging sensor 24 may also be enabled to optically detect physical contacts with the surfaces of the keys 41, by imaging the physical contacts through the waveguide 30, in another detection mode. Even before a user touches a particular key, the imaging sensor 24 may already detect and provide tracking for the user's finger. Imaging sensor 24 may therefore optically detect when the user's finger touches the surface of one of the keys 41. This may provide the capability to treat a particular key as being pressed as soon as the user touches it. Different detection modes and different embodiments may therefore provide any combination of a variety of detection modes that configure imaging sensor 24 to optically detect physical contacts with the one or more display surfaces.

Imaging sensor 24 may further be configured to distinguish a variety of different modes of physical contact with the display surfaces. For example, imaging sensor may be configured to distinguish between the physical contact of a user's finger with a particular key and the key being pressed. It may distinguish if the user's finger makes sliding motions in one direction or another across the surface of one of the keys, or how slowly or how forcefully one of the keys is pressed. Dynamic rear-projected user interface device 10A may therefore be enabled to read a variety of different inputs for a single one of the keys 41, as a function of the characteristics of the physical contact with that display surface. These different input modes per a particular key may be used in different ways by different applications running on an associated computing system.

For example, a game application may be running on the associated computing system, a particular key on the keyboard may control a particular kind of motion of a player-controlled element in the game, and the speed with which the user runs her finger over that particular key may be used to determine the speed with which that particular kind of motion is engaged in the game. As another illustrative example, a music performance application may be running, with different keys on keyboard 40 (or on a different keyboard with a piano-style musical keyboard layout, for example) corresponding to particular notes or other controls for performing music, and the slowness or forcefulness with which the user strikes one of the keys may be detected and translated into that particular note sounding softly or loudly, for example. Many other possible usages are possible, and may be freely used by developers of applications making use of the different input modes enabled by dynamic rear-projected user interface device 10A.

In another illustrative embodiment, the imaging sensor 24 may be less sensitive to the imaging details of each of the particular keys 41, or the keys 41 may be insufficiently transparent to detect details of physical contact by the user, or plural input modes per key may simply not be a priority, and the imaging sensor 24 may be configured merely to optically detect physical displacement of the keys 41. This in itself provides the considerable advantage of implementing an optical switching mode for the keys 41, so that keyboard 40 requires no internal mechanical or electrical switching elements, and requires no moving parts other than the keys themselves. In this and a variety of other embodiments, the keys may include a typical concave form, in addition to enabling typical up-and-down motion and other tactile cues that users typically rely on in using a keyboard rapidly and efficiently. This provides advantages over virtual keys projected onto a flat surface, and to keys in which the top surface is occupied by an LCD screen, which thereby is flat rather than having a concave form, and thereby may provide less of the tactile cues that efficient typists rely on in using a keyboard. Since the up-and-down motion of the keys is detected optically, and has no electrical switch for each key as in a typical keyboard or electronics package devoted to each key as in some newer keyboards, the keys 41 of keyboard 40 may remain mechanically durable long after mechanical wear-and-tear would degrade or disable the electrical switches or electronic components of other keyboards.

In yet another embodiment, the keys 41 may be mechanically static and integral with keyboard 40, and the imaging sensor 24 may be configured to optically detect a user striking or pressing the keys 41, so that keyboard 40 becomes fully functional with no moving parts at all, while the user still has the advantage of the tactile feel of the familiar keys of a keyboard. In yet other embodiments mechanical keys may be eliminated entirely and the images may simply be transferred to the surface of the diffuser 60, for example, so that the diffuser 60 acts like a touch-screen surface in which the user input is optically detected.

A wide variety of kinds of keypads may be used in place of keyboard 40 as depicted in FIG. 1, together with components such as light source 12, projection controller 20, imaging sensor 24, and waveguide 30. For example, other kinds of keypads that may be used with a device otherwise similar to dynamic rear-projected user interface device 10A of FIG. 1 include a larger keyboard with additional devoted sections of function keys and numeric keys; an ergonomic keyboard divided into right and left hand sections angled to each other for natural wrist alignment; a devoted numeric keypad; a devoted game controller; a musical keyboard, that is, with a piano-style layout of 88 keys, or an abbreviated version thereof, and so forth.

FIGS. 2A and 2B depict the same dynamic rear-projected user interface device 10A as in FIG. 1, but in different views, here labeled as 10B and 10C. FIG. 2A includes coordinate set 99B, while FIG. 2B includes coordinate set 99A as it appears in FIG. 1, to indicate that dynamic rear-projected user interface device 10A is depicted in the same orientation as in FIG. 1, although in a cutaway (and further simplified) version in FIG. 2B to showcase the operation of waveguide 30. FIG. 2A is also intended to demonstrate further the operation of waveguide 30, from a side view. As indicated by coordinate set 99B, the view of FIG. 2A corresponds to the X direction, from left to right side of keyboard 40, going “into the page”, perpendicular to the view of this figure; the Y direction, indicating bottom to top of keyboard 40, is here going from right to left; and the Z direction, indicating the direction perpendicular to the plane of keyboard 40, is here going from down to up. Analogously to the depiction of FIG. 1, dynamic rear-projected user interface device 10B, 10C includes a light source 12B, an imaging controller 20B, an imaging sensor 24B, a waveguide nexus 32, and a communication interface 29B, in an analogous functional arrangement as described above with reference to FIG. 1.

Waveguide 30 includes an expansion portion 31 and an image portion 33. Expansion portion 31 has horizontal boundaries 34 and 35 (shown in FIG. 2B) that diverge along a projection path away from the light source 12, and vertical boundaries 34 and 35 (shown in FIG. 2A) that are substantially parallel. Image portion 33 has vertical boundaries 36 and 37 that are angled relative to each other. Light source 12B is positioned in interface with the expansion portion 31 by means of waveguide nexus 32. Waveguide nexus 32 is a part of waveguide 30 that magnifies the light beams 19A and 19B from light source 12B and reflects them onto their paths into expansion portion 31, as particularly seen in FIG. 2B. The image portion 33 is positioned in interface with the display surface of the keyboard 40, such that rays emitted by the projector 12B are internally reflected throughout the expansion portion 31 to propagate to image portion 33, and are transmitted from the image portion 33 through a spatial light modulator 50 and a diffuser 60, after which the resulting images are projected onto the keys 41, as further elaborated below.

As FIG. 2A demonstrates, waveguide 30 is substantially flat, and tapered along its image portion 33. Waveguide 30 is disposed between the spatial light modulator 50 at one end, and the light source 12B and imaging sensor 24B at the other end. Waveguide 30 and its boundaries 34, 35, 36, 37 are configured to convey rays of light, such as representative projection ray paths 19A and 19B, with total internal reflection through expansion portion 31 and to convey the light rays by total internal reflection through a portion of image portion 33 as needed before directing each ray in the beam at upper boundary 36 at an angle past the critical angle, and which may be orthogonal or relatively close to orthogonal to the display surface on which the SLM 50, diffuser 60 and keys 41 are located, to thereby cause the rays to be transmitted through the upper boundary 36 of image portion 33. The critical angle for distinguishing between internal reflection and transmission is determined by the index of refraction of both the substance of waveguide 30 and that of its boundaries 36 and 37. Waveguide 30 may be composed of acrylic, polycarbonate, glass, or other appropriate materials for transmitting optical rays, for example. The boundaries 34, 35, 36 and 37 may be composed of any appropriate optical cladding suited for reflection.

Numerous variants of waveguide 30 may also be employed. For instance, in one implementation the waveguide may be optically folded to conserve space.

Spatial light modulator 50 modulates the income light beam 19. A spatial light modulator consists of an array of optical elements in which each element acts independently as an optical “valve” to adjust or modulate light intensity. A spatial light modulator does not create its own light, but rather modulates (either reflectively or transmissively) light from a source to create a dynamically adjustable image that can be projected onto a surface. The optical elements or valves are controlled by an SLM controller (not shown) to establish the intensity level of each pixel in the image. In the present implementation images created by the SLM 50 are projected through diffuser 60 onto the interior or lower surfaces of the keys 41. Technologies that have been used as spatial light modulators include liquid crystal devices or displays (LCDs), acousto-optical modulators, micromirror arrays such as micro-electro-mechanical (MEMs) devices and grating light valve (GLV) device.

The keys 41 serve as display surfaces, which may be semi-transparent and diffuse so that they are well suited to forming display images that are easily visible from above due to optical projections from below, as well as being suited to admitting optical images of physical contacts with the keys 41. The surfaces of keys 41 may also be coated with a turning film, which may ensure that the image projection rays emerge at an angle with respect to the Z direction so that the principle rays emerge in a direction pointing directly toward the viewer. The turning film may in turn be topped by a scattering screen on each of the key surfaces, to enhance visibility of the display images from a wide range of viewing angles.

The display images that are projected onto the keys 41 are indicative of a first set of input controls when the computing device is in a first operating context, and a second set of input controls when the computing device is in a second operating context. That is, one set of input controls may include a typical layout of keys for orthographic characters such as letters of the alphabet, additional punctuation marks, and numbers, along with basic function keys such as “return”, “backspace”, and “delete”, along with a suite of function keys along the top row of the keyboard 40.

While function keys are typically labeled simply “F1”, “F2”, “F3”, etc., the projector provides images onto the corresponding keys that explicitly label their function at any given time as dictated by the current operating context of the associated computing system. For example, the top row of function keys that are normally labeled “F1”, “F2”, “F3”, etc., may instead, according to the dictates of one application currently running on an associated computing system, be labeled “Help”, “Save”, “Copy”, “Cut”, “Paste”, “Undo”, “Redo”, “Find and Replace”, “Spelling and Grammar Check”, “Full Screen View”, “Save As”, “Close”, etc. Instead of a user having to refer to an external reference, or have to remember the assigned functions for each of the function keys as assigned by a particular application, the actual words indicating the particular functions appear on the keys themselves for the application or other operating context that currently applies.

The dynamic rear-projected user interface device 10A thereby takes a different tack from the effort to provide images to key surfaces by means of a local LCD screen or other electronically controlled screen on every key, each key with the associated electronics. Rather than sending electrical signals from a central source to an electronics and screen package at each of the keys, photons are generated from a central source (e.g., light source 12) and optically guided to the surfaces of the keys via a spatial light modulator, thereby eliminating the need to incorporate an LCD display and associated electronics in each of the keys. This may use light waveguide technology that can convey photons from entrance to exit via one or more waveguides, which may be implemented as simply as a shaped clear plastic part, as an illustrative example. This provides advantages such as greater mechanical durability, water resistance, and lower cost, among others.

Light source 12B may project a monochromatic light beam, or may use a collection of different colored beams in combination to create full-color display images on keys 41 or keyboard 40. Light source 12B may also include a non-visible light emitter that emits a non-visible form of light such as an infrared light, for example, and the imaging sensor may be configured to image reflections of the infrared light as they are visible through the surfaces of the keys 41. This provides another illustrative example of how a user's fingers may be imaged and tracked in interfacing with the keys 41, so that multiple input modes may be implemented for each of the keys 41, for example by tracking an optional lateral direction in which the surfaces of the keys are stroked in addition to the basic input of striking the keys vertically.

Because the boundaries 34, 35 of expansion portion 31 are parallel and the boundaries 36, 37 of second waveguide section are angled relative to each other at a small angle, waveguide 30 is able to propagate a beam of light provided by small light source 12B, through a substantially flat package, to backlight the spatial light modulator 50 and to convey images back to imaging sensor 24B. Waveguide 30 is therefore configured, according to this illustrative embodiment, to enable imaging sensor 24B to receive images such as user gestures and the like that are provided through the surfaces of keys 41 (only a sampling of which are explicitly indicated in FIG. 2A). In this same manner imaging sensor 24B can detect physical displacement of the keys 41. The specific details of the embodiment of FIGS. 2A and 2B are exemplary and do not connote limitations. For example, a few other illustrative embodiments are provided in the subsequent figures.

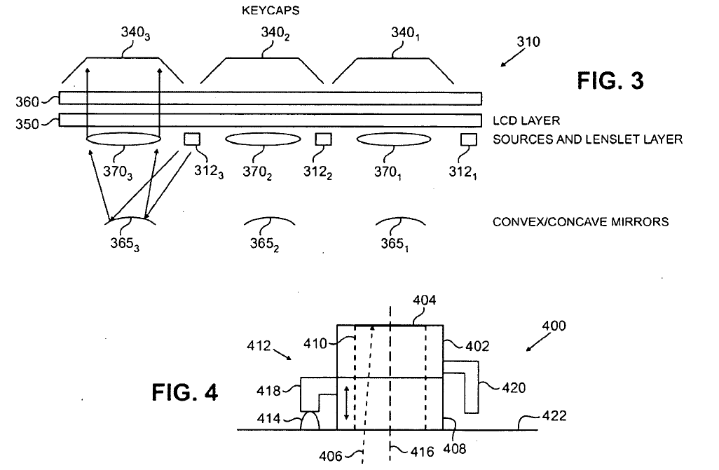

In the embodiments described above the waveguide 30 is used to deliver a collimated beam of light that is used to backlight an LCD. More generally, however, any suitable optical element or group of optical elements may be used to deliver the collimated light. For example coherent fiber bundle, GRIN lens or a totally internally reflecting lens may be employed. FIG. 3 shows a simplified schematic diagram of an embodiment of the dynamic rear-projected user interface 310 which employs a plurality of light sources 312, concave mirrors 365 and collimating lenses 370. The light sources 312 and the collimating lenses 370 are located on a surface below the diffuser 360 and the LCD layer 350. In this example one light source, mirror and collimating lens is provided for each key. For instance, light source 312₁, mirror 365₁ and collimating lens 370₁ are associated with key 340₁. Likewise, light source 312₂, mirror 365₂ and collimating lens 370₂ are associated with key 340₂ and light source 312₃, mirror 365₃ and collimating lens 370₃ are associated with key 340₃. The arrows show the paths traversed by the lights rays from light sources 312 to the surface of the keys 340. While in this implementation one light source 312 is provided for each key 340, more generally any ratio of light source 312 to keys 340 may be employed. For instance, in some cases it may be sufficient to provide a single light source for a set of four or more keys while still maintaining adequate uniformity in intensity. Uniformity may be further enhanced with the addition of micro-optic concentrator elements or homogenizer elements. The embodiment shown in FIG. 3 is a folded architecture that employs concave mirrors 365 to minimize the overall thickness of the user interface device 310. In other embodiments in which this is not a concern the mirrors 365 may be eliminated and the light sources 312 may be located below the current location of the mirrors 365 in FIG. 3.

The keys 41 that are employed in keypad 40 should provide maximum viewing area on the key button tops for the display of information. Examples of such keys are described in U.S. patent application Ser. Nos. 11/254,355 and 12/240,017, which are hereby incorporated by reference in their entirety. FIG. 4 shows a cross-sectional view of the mechanical architecture of a key shown in U.S. patent application Ser. Nos. 11/254,355 and 12/240,017, that optimizes the aperture through the core of the key switch assembly in order to project an image through the aperture and onto the display area of the key button. The architecture moves the tactile feedback mechanism (e.g., dome assembly) out from underneath the key button to the perimeter or side of the key switch assembly.

Referring to FIG. 4, a key switch assembly 400 for display-type keys for user input devices is shown. The switch assembly 400 includes, generally, a key button 402 (represented generally as a block) having a display portion 404 onto which light 406 is directed for viewing display information, such as letters, characters, images, video, other markings, etc. The display portion 404 can be a separate piece of translucent or transparent material embedded into the top of the key button 402 that allows the light imposed on the underlying surface of the display portion 404 to be perceived on the top surface of the display portion 404.

The switch assembly 400 also includes a movement assembly 408 (represented generally as a block) in contact with the key button 402 for facilitating vertical movement of the key button 402. The movement assembly 408 defines an aperture 410 through which the light 406 is projected onto the display portion 404. Additionally, the structure of the key button 402 can also allow the aperture 410 to extend into the key button structure; however, this is not a requirement, since alternatively, the key button 402 can be a solid block of material into which the display portion 404 is embedded; the display portion extending the full height of the key button 402 from the top surface to the bottom surface.

A feedback assembly 412 of the switch assembly 400 can include an elastomeric (e.g., rubber, silicone, etc.) dome assembly 414 that is offset from a center axis 416 of the key button 402 and in contact with the movement assembly 408 for providing tactile feedback to the user. It is to be understood that multiple dome assemblies can be utilized with each key switch assembly 400. The feedback assembly 412 may optionally include a feedback arm 418 that extends from the movement assembly 408 and compresses the dome assembly 414 on downward movement of the key button 402.

The switch assembly 400 also includes contact arm 420 that enters close proximity with a surface 422 when the key button 402 is in the fully down mode. When in close proximity with the surface 422, the contact arm 420 can be sensed, indicating that the key button 402 is in the fully down position. The contact arm 420 can be affixed to the key button 402 or the movement assembly 408 in a suitable manner that allows the fully down position to be sensed when in contact with or sufficiently proximate to the surface 422.

The structure of switch assembly 400 allows the projection of an image through the switch assembly 400 onto the display portion 404. It is therefore desirable to move as much hardware as possible away from the center axis 416 to provide the optimum aperture size for light transmission and image display. In support thereof, as shown, the feedback assembly 412 can be located between the keys and outside the general footprint defined by the key button 402 and movement assembly 408. However, it is to be understood that other structural designs that place the feedback assembly closer to the footprint or in the periphery of the footprint fall within the scope of the disclosed architecture. Moreover, it is to be understood that the feedback assembly 412 can be placed partially or entirely in the aperture 410 provided there is suitable space remaining in the aperture 410 to allow the desired amount of light 406 to reach the display portion 404. Additional details concerning the key shown in FIG. 4 may be found in the aforementioned patent application.

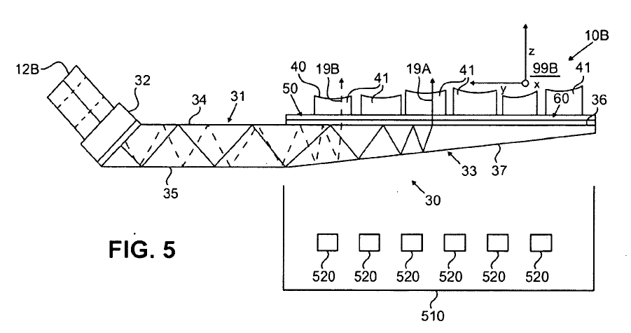

FIG. 5 shows another embodiment of the dynamic rear-projected user interface 310 in which the image sensor 24 shown in FIG. 1 is relocated. In FIG. 5 an image or camera array 510 is situated below the image portion 33 of the waveguide 30. The image array 510 includes a series of image sensors 520 the receive images from the surface of the keys 41. Image array 510 may therefore provide interactive functionality that is similar to the functionality of image sensor 24, including the ability to detect physical contact with the keys 41, detect motion of the keys 41, as well as distinguish between different types of motion. Similar to image sensor 24 shown in FIG. 1, image array 510 may incorporate any type of imaging sensor, including but not limited to a CMOS array or a CCD. While not shown, a variety of optical arrangements may be provided in the optical path between the image array 510 and the keys 41, including, for instance, a telecentric lens arrangement, a collimating lens arrangement, a semi-transparent turning film, and a concentrator. In addition, one or more non-visible light emitters may be associated with the image array 510 that can be used to illuminate objects being detected by the image array 510. The non-visible light (e.g., infrared light) that is emitted should be of a frequency that is detectable by the individual image sensors 24.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims. As a particular example, while the terms “computer”, “computing device”, or “computing system” may herein sometimes be used alone for convenience, it is well understood that each of these could refer to any computing device, computing system, computing environment, mobile device, or other information processing component or context, and is not limited to any individual interpretation. As another particular example, while many embodiments are presented with illustrative elements that are widely familiar at the time of filing the patent application, it is envisioned that many new innovations in computing technology will affect elements of different embodiments, in such aspects as user interfaces, user input methods, computing environments, and computing methods, and that the elements defined by the claims may be embodied according to these and other innovative advances while still remaining consistent with and encompassed by the elements defined by the claims herein.

1. A user interface device, comprising:
a keypad having a plurality of actuable keys;
at least one light source for generating a light beam;
a spatial light modulator for receiving and dynamically modulating the light beam to create a plurality of display images that are respectively projected onto the plurality of keys; and
an optical arrangement disposed in an optical path between the light source and the spatial light modulator for conveying the light beam from the light source to the spatial light modulator.

2. The device of claim 1 wherein the optical arrangement comprises a waveguide having an expansion and an image portion, wherein the light source and the image portion are positioned such that light rays generated by the light source are internally reflected throughout the expansion portion and are transmitted from the image portion to the spatial light modulator.

3. The device of claim 1 wherein the keys include at least a partially optically transparent portion onto which the display images are projected.

4. The device of claim 3 further comprising an imaging sensor configured to optically detect physical contact with the one or more keys.

5. The device of claim 4 further comprising a non-visible light emitter, wherein the imaging sensor is configured to image reflections of the non-visible light received from the keys.

6. The device of claim 5 wherein the imaging sensor is further configured to detect a plurality of different modes of physical contact with the keys such that a plurality of different inputs are enabled for a single one of the keys.

7. The device of claim 1 further comprising a diffuser located between the spatial light modulator and the keys.

8. The device of claim 1 wherein the spatial light modulator is an LCD array.

9. The device of claim 4 wherein the imaging sensor detects physical contact with the one or more keys by receiving non-visible light from the optical arrangement.

10. The device of claim 1 wherein the plurality of actuable keys comprises a common display surface onto which display images are projected.

11. The device of claim 1 wherein the plurality of actuable keys comprises a plurality of mechanical keys each having a key button with a display portion onto which the display images are projected and a movement assembly in contact with the key button for facilitating movement of the key button, the movement assembly defining an aperture through which the display images are projected onto the display portion.

12. The device of claim 1 wherein the at least one light source includes a plurality of light sources and the optical arrangement includes a plurality of lenses for delivering collimated light from the light sources to the keys through the spatial light modulator.

13. The device of claim 2 further comprising an imaging array configured to optically detect physical contact with the one or more keys, said imaging array including a plurality of imaging sensors positioned to receive non-visible light transmitted through the converging boundaries of the image portion of the waveguide.

14. A medium comprising instructions executable by a computing system, wherein the instructions configure the computing system to:
project a light beam;
collimate the light beam; and
spatially modulate the light beam to create a plurality of display images that are respectively projected onto a user-input receiving surface such that the plurality of display image represent a first set of input controls when a computing device is in a first operating context and second set of input controls when the computing device is in a second operating context.

15. The medium of claim 14 wherein the user-input receiving surface includes a plurality of keys onto which the plurality of display images is respectively projected.

16. The medium of claim 14 wherein the instructions configure the computing system to spatially modulate the light beam by backlighting an LCD array with the light beam after it has been collimated.

17. The medium of claim 15 wherein the instructions further configure the computing system to optically detect physical displacement of the keys.

18. The medium of claim 17 wherein the instructions configure the computing system to collimate the light beam with a waveguide having a tapered portion and optical detection of physical displacement of the keys is performed by detecting non-visible light received through the waveguide.

19. The medium of claim 15 wherein the instructions configure the computing system to detect a plurality of different modes of physical contact with the keys such that a plurality of different inputs are enabled for a single one of the keys.

20. The medium of claim 19 wherein the instructions configure the computing system to detect the plurality of different modes of physical contact with the keys by receiving non-visible light transmitted though a partially optically transparent portion of the keys onto which the display images are projected.
